(19) United States
(12) Patent Application Publication
(10) Pub. No.: US 2026/0164606 A1
(43) Pub. Date: Jun. 11, 2026

(54) ELECTRONIC APPARATUS

(71) Applicant: INDUSTRIAL TECHNOLOGY RESEARCH INSTITUTE, Hsinchu (TW)

(72) Inventors: Ya-Chi HO, New Taipei City (TW); Tsai-Liang WU, Hsinchu County (TW); Da-Jeng YAO, Taipei City (TW); Chien-Yu LIN, Kaohsiung City (TW); Wun-Yi LI, Taoyuan City (TW)

(73) Assignee: INDUSTRIAL TECHNOLOGY RESEARCH INSTITUTE, Hsinchu (TW)

(21) Appl. No.: 19/045,824

(22) Filed: Feb. 5, 2025

(30) Foreign Application Priority Data
Dec. 10, 2024 (TW) 113147914

(51) Int. Cl. H05K 7/20

(52) U.S. Cl. CPC H05K 7/20336; H05K 7/203

(57) ABSTRACT

An electronic apparatus includes a tank, an electronic module and a heat exchange module. The electronic module is disposed in the tank and immersed into a first coolant. The heat exchange module includes pulsating heat pipes and a heat exchanger. The pulsating heat pipes are partially located in the tank to be immersed into the first coolant, each of the pulsating heat pipes is filled with a working fluid and a surfactant, and a vacuum degree of each of the pulsating heat pipes is smaller than or equal to 8.0×10⁻² torr. The heat exchanger includes a casing and a heat sink, the heat sink is located in a heat exchange chamber of the casing, the pulsating heat pipes are disposed through the casing and are thermally coupled to the heat sink, and the heat sink performs heat exchange with a second coolant in the heat exchange chamber.

### CROSS-REFERENCE TO RELATED APPLICATIONS

All related applications are incorporated by reference. The present application is based on, and claims priority from, Taiwan (International) Application Serial Number 113147914 filed on Dec. 10, 2024, the disclosure of which is hereby incorporated by reference herein in its entirety.

### TECHNICAL FIELD

The disclosure relates to an electronic apparatus.

### BACKGROUND

As technology progresses and develops, a thermal design power of a processor in an electronic device (e.g., a server) gradually increases, and thus a heat dissipation device may correspondingly consume more electricity to dissipate heat generated by the processor, such that the processor can operate in an adequate temperate. However, this causes the electricity consumption to be difficult to be reduced. As a result, how to solve the aforementioned issue is one of the topics in this field.

### SUMMARY

One embodiment of the disclosure provides an electronic apparatus. The electronic apparatus includes a tank, at least one electronic module and an immersion-typed heat exchange module. The tank is configured to accommodate a first coolant. The electronic module is disposed in the tank and immersed into the first coolant. The immersion-typed heat exchange module includes a plurality of pulsating heat pipes and a heat exchanger. The pulsating heat pipes are partially located in the tank to be immersed into the first coolant, each of the pulsating heat pipes is filled with a working fluid and a surfactant, and a vacuum degree of each of the pulsating heat pipes is smaller than or equal to 8.0×10⁻² torr. The heat exchanger includes a casing and a heat sink, the casing has an inlet channel, a heat exchange chamber and an outlet channel, the inlet channel and the outlet channel communicate with the heat exchange chamber, the heat sink is located in the heat exchange chamber, the pulsating heat pipes are disposed through the casing and are thermally coupled to the heat sink, and the heat sink is configured to perform heat exchange with a second coolant in the heat exchange chamber.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a perspective view of an electronic apparatus according to one embodiment of the disclosure;

FIG. 2 is a partial exploded view of the electronic apparatus in FIG. 1; and

FIG. 3 is a partial cross-sectional view of the electronic apparatus in FIG. 1.

### DETAILED DESCRIPTION

In the following detailed description, for purpose of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

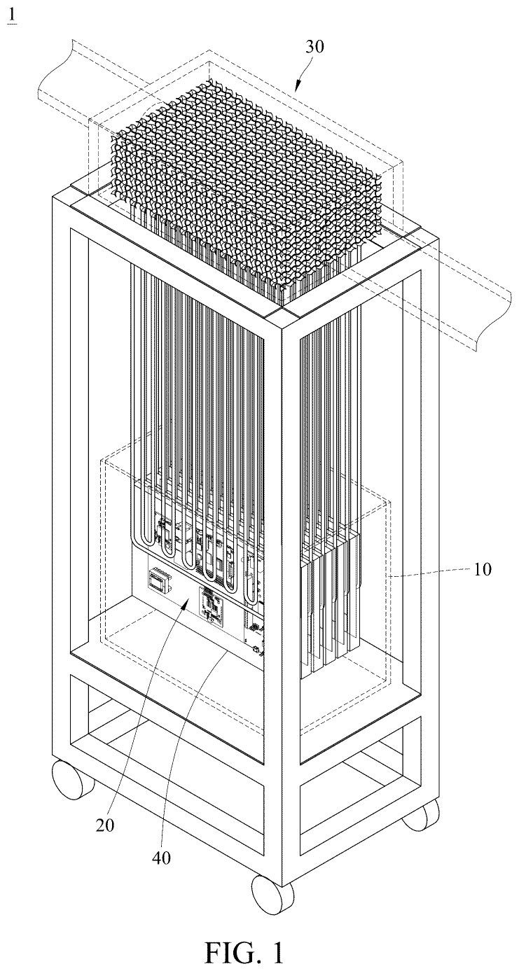

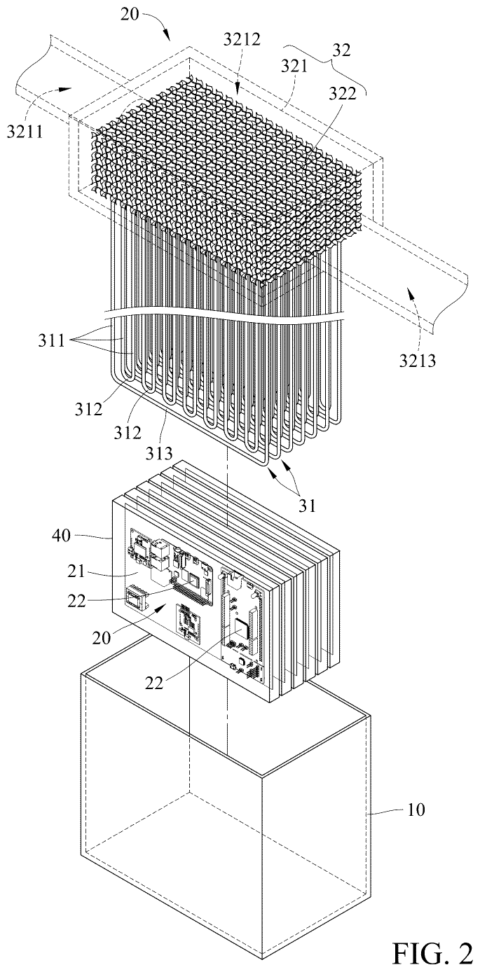

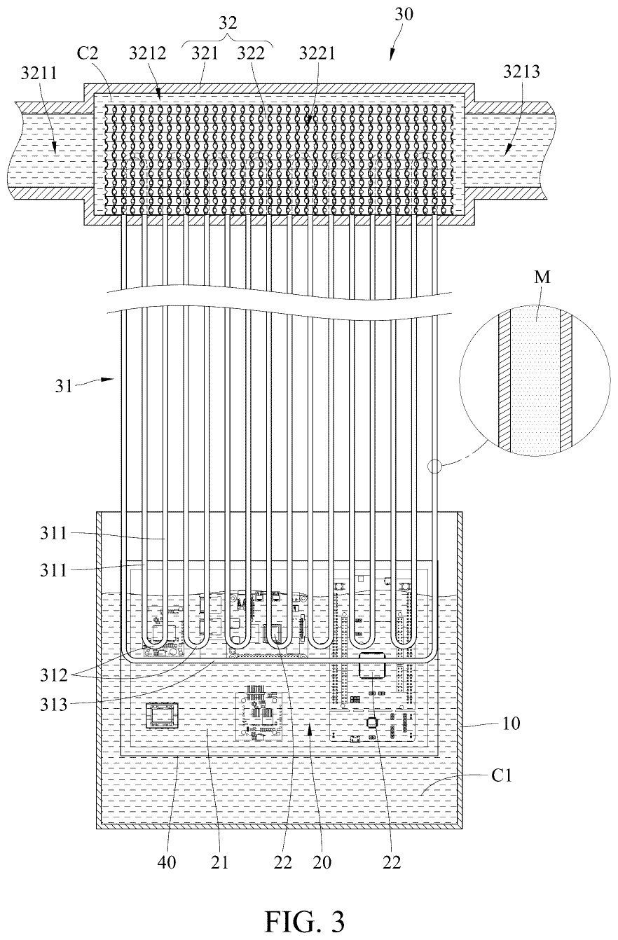

Referring to FIGS. 1 to 3, FIG. 1 is a perspective view of an electronic apparatus according to one embodiment of the disclosure, FIG. 2 is a partial exploded view of the electronic apparatus in FIG. 1, and FIG. 3 is a partial cross-sectional view of the electronic apparatus in FIG. 1.

In this embodiment, the electronic apparatus 1 includes a tank 10, a plurality of electronic modules 20 and an immersion-typed heat exchange module 30. In addition, the electronic apparatus 1 may further include at least one insulation layer 40.

The tank 10 is configured to accommodate a first coolant C1. The first coolant C1 is, for example, a conductive liquid, such as a nature water, where the nature water can be river water, ocean water, lake water, well water and so on.

In a case that there are a plurality of electronic modules 20, a plurality of insulation layers 40 may be used to respectively wrap the electronic modules 20. The electronic modules 20 wrapped with the insulation layers 40 are immersed into the first coolant C1, and the insulation layers 40 insulate the electronic modules 20 from the first coolant C1. In one embodiment, a single insulation layer 40 may be used to wrap all of the electronic modules. In addition, the quantity of the electronic modules 20 is not restricted to being plural. In one embodiment, there may be a single electronic module, and the single insulation layer 40 may be used to wrap this electronic module.

Note that the first coolant C1 is not restricted to being the conductive nature water. In some other embodiment, the first coolant may be a non-conductive dielectric liquid, such as a fluorinated liquid. As a result, the insulation layers can be omitted.

In this embodiment, the quantity of the electronic modules 20 is plural and corresponds to the quantity of the insulation layers 40. Each of the electronic modules 20, for example, includes a motherboard 21, and the motherboard 21 is provided with a plurality of heat sources 22, such as a CPU and other electronic components. Heat generated by the heat sources 22 of the electronic modules 20 can be conducted to the first coolant C1 in the tank 10 via the insulation layers 40.

A resistivity of each of the insulation layers 40 is, for example, greater than 10⁶ Ω·m. The insulation layers 40 have characteristic of electrical insulation and are resistant to corrosion of natural water and acid/alkali, and the insulation layers 40 are chemically stable. The material of each of the insulation layers 40, for example but not limited to, includes polycarbonate, polyethylene terephthalate, polybutylene terephthalate, polypropylene, polyethylene naphthalate, nylon, polyphenylene sulfide, polytetrafluoroethylene, polyethylene or ethylene vinyl acetate and so on.

The immersion-typed heat exchange module 30 includes a plurality of pulsating heat pipes 31 and a heat exchanger 32.

The pulsating heat pipes 31 are partially located in the tank 10, and are partially located between the electronic modules 20, respectively. The pulsating heat pipes 31 are immersed into the first coolant C1. The pulsating heat pipes 31 have the same structure, and the following descriptions merely introduce one of them. The pulsating heat pipe 31 is filled with a mixture M of a working fluid and a surfactant, and a vacuum degree of the pulsating heat pipe 31 is smaller than or equal to 8.0×10⁻² torr.

In this embodiment, a specific heat capacity of the working fluid is, for example, not less than 50 J/(kg·K) and not more than 5000 J/(kg·K), and a latent heat of the working fluid is, for example, not less than 4 kJ/kg and not more than 4500 kJ/kg. In other words, the specific heat capacity of the working fluid is, for example, greater than or equal to 50 J/(kg·K) and is smaller than or equal to 5000 J/(kg·K), and the latent heat of the working fluid is, for example, greater than or equal to 4 kJ/kg and smaller than or equal to 4500 kJ/kg. In addition, the surfactant, for example but not limited to, includes one of alkylbenzene sulfonate, sodium dodecyl sulfate, hexadecyl trimethyl ammonium bromide and glutamic acid.

Then, the following descriptions will specifically introduce the structure of the pulsating heat pipe 31. The pulsating heat pipe 31 includes a plurality of straight portions 311, a plurality of curved portions 312 and a connection portion 313. The straight portions 311 are arranged to be parallel and spaced apart from each other. The curved portions 312 are connected to the straight portions 311. Two of the straight portions 311 located outermost are connected to each other via the connection portion 313.

In this embodiment, the quantity of the curved portions 312 of each of the pulsating heat pipes 31 is, for example, at least four.

The heat exchanger 32 includes a casing 321 and a heat sink 322. The casing 321 has an inlet channel 3211, a heat exchange chamber 3212 and an outlet channel 3213, and the inlet channel 3211 and the outlet channel 3213 communicate with the heat exchange chamber 3212. The heat sink 322 is, for example, a porous heat sink (e.g., with wavy fins), and has a plurality of holes 3221. A porosity of the heat sink 322 is greater than or equal to 5% and is smaller than or equal to 95%. The heat sink 322 is located in the heat exchange chamber 3212. The pulsating heat pipes 31 are disposed through the casing 321 and are thermally coupled to the heat sink 322. For example, the pulsating heat pipes 31 are integrally connected to the heat sink 322. The heat sink 322 is configured to perform heat exchange with a second coolant C2 in the heat exchange chamber 3212, where the second coolant C2 may be the same as the first coolant C1 (e.g., nature water), or the second coolant C2 may be different from the first coolant C1.

During the operation of the electronic modules 20, the heat sources 22 of the electronic modules 20 generate heat, and heat is conducted to the first coolant C1 in the tank 10 via the insulation layers 40. Then, the pulsating heat pipes 31 partially immersed into the first coolant C1 in the tank 10 conduct heat to the heat sink 322. Then, the second coolant C2 flowing into the heat exchange chamber 3212 from the inlet channel 3211 of the casing 321 performs heat exchange with the heat sink 322, and then flows out of the casing 321 from the outlet channel 3213 so as to take heat away.

In this embodiment, the pulsating heat pipes 31 which do not require electricity are partially located in the tank 10 to be immersed into the first coolant C1, the pulsating heat pipes 31 are filled with the working fluid and the surfactant, the vacuum degrees of the pulsating heat pipes 31 are smaller than or equal to 8.0×10⁻² torr, the heat sink 322 is located in the heat exchange chamber 3212 of the casing 321, the pulsating heat pipes 31 are disposed through the casing 321 and are thermally coupled to the heat sink 322, and the heat sink 322 is configured to perform heat exchange with the second coolant C2 in the heat exchange chamber 3212, which can conduct heat generated by the electronic modules 20 to the heat sink 322 via the first coolant C1 and the pulsating heat pipes 31 which do not require electricity, such that heat can be taken away by the second coolant C2, thereby maintaining the heat dissipation efficiency while saving electricity.

Taking a case that a heat exchanger requiring electricity conducts heat to the heat sink 322 for example, the heat exchanger requires electricity, and thus the power usage effectiveness (i.e., PUE) of the entire apparatus is about 1.02. As for this embodiment, since the pulsating heat pipes 31 which do not require electricity replace the heat exchanger requiring electricity, the power usage effectiveness (i.e., PUE) of the entire apparatus can be decreased to about 1.005, thereby saving electricity.

In addition, the working fluid in the pulsating heat pipes 31 is mixed with the surfactant, which can destroy the surface tension of the working fluid. Moreover, the vacuum degree of each of the pulsating heat pipes 31 is smaller than or equal to 8.0×10⁻² torr, which can decrease the saturated vapor pressure of the working fluid, thereby reducing the activation temperature of the working fluid; that is, the boiling temperature of the working fluid can be decreased, such that the working fluid can rapidly and massively absorb heat from the first coolant C1 in a low temperature (e.g., 30° C.) and conduct heat to the heat sink 322 for achieving the desired heat dissipation efficiency.

Note that the specific heat capacity and the latent heat of the working fluid in the pulsating heat pipes 31 are not restricted to falling within the aforementioned range and may be modified according to actual requirements.

In addition, the surfactant is not restricted to including one of alkylbenzene sulfonate, sodium dodecyl sulfate, hexadecyl trimethyl ammonium bromide and glutamic acid and may be modified according to actual requirements.

Then, the structures of the pulsating heat pipes 31 are not restricted in the disclosure and may be modified according to actual requirements. For example, the quantity of the curved portions of each of the pulsating heat pipes may be modified according to actual requirements.

In one embodiment, the quantity of the pulsating heat pipes 31 is at least four.

In this embodiment, the heat sink 322 is the porous heat sink (e.g., with wavy fins), and the porosity thereof is greater than or equal to 5% and is smaller than or equal to 95%, which can increase the heat exchange efficiency between the heat sink 322 and the second coolant C2. Note that the heat sink 322 is not restricted to being the porous heat sink with the wavy fins. In some other embodiments, the heat sink may be another type and include a plurality of flat-sheet-shaped fins.

According to the electronic apparatus as discussed in the above embodiment, the pulsating heat pipes which do not require electricity are partially located in the tank to be immersed into the first coolant, the pulsating heat pipes are filled with the working fluid and the surfactant, the vacuum degrees of the pulsating heat pipes are smaller than or equal to 8.0×10⁻² torr, the heat sink is located in the heat exchange chamber of the casing, the pulsating heat pipes are disposed through the casing and are thermally coupled to the heat sink, and the heat sink is configured to perform heat exchange with the second coolant in the heat exchange chamber, which can conduct heat generated by the electronic modules to the heat sink via the first coolant and the pulsating heat pipes which do not require electricity, such that heat can be taken away by the second coolant, thereby maintaining the heat dissipation efficiency while saving electricity.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. An electronic apparatus, comprising:
a tank, configured to accommodate a first coolant;
at least one electronic module, disposed in the tank and immersed into the first coolant; and
an immersion-typed heat exchange module, comprising:
a plurality of pulsating heat pipes, partially located in the tank to be immersed into the first coolant, wherein each of the plurality of pulsating heat pipes is filled with a working fluid and a surfactant, and a vacuum degree of each of the plurality of pulsating heat pipes is smaller than or equal to 8.0×10⁻² torr; and
a heat exchanger, comprising a casing and a heat sink, wherein the casing has an inlet channel, a heat exchange chamber and an outlet channel, the inlet channel and the outlet channel communicate with the heat exchange chamber, the heat sink is located in the heat exchange chamber, the plurality of pulsating heat pipes are disposed through the casing and are thermally coupled to the heat sink, and the heat sink is configured to perform heat exchange with a second coolant in the heat exchange chamber.

2. The electronic apparatus according to claim 1, wherein the surfactant comprises one of alkylbenzene sulfonate, sodium dodecyl sulfate, hexadecyl trimethyl ammonium bromide and glutamic acid.

3. The electronic apparatus according to claim 1, wherein a specific heat capacity of the working fluid is not less than 50 J/(kg·K) and not more than 5000 J/(kg·K), and a latent heat of the working fluid is not less than 4 kJ/kg and not more than 4500 kJ/kg.

4. The electronic apparatus according to claim 1, wherein each of the plurality of pulsating heat pipes comprises a plurality of straight portions, a plurality of curved portions and a connection portion, the plurality of straight portions are arranged to be parallel and spaced apart from each another, the plurality of curved portions are connected to the plurality of straight portions, and two of the plurality of straight portions located at outermost are connected to each other via the connection portion.

5. The electronic apparatus according to claim 4, wherein the at least one electronic module comprises a plurality of electronic modules, the plurality of electronic modules are arranged to be spaced apart from each other, and the plurality of pulsating heat pipes are partially located between the plurality of electronic modules, respectively.

6. The electronic apparatus according to claim 5, wherein a quantity of the plurality of curved portions of each of the plurality of pulsating heat pipes is at least four.

7. The electronic apparatus according to claim 1, wherein the plurality of pulsating heat pipes are integrally connected to the heat sink.

8. The electronic apparatus according to claim 1, wherein the heat sink is a porous heat sink.

9. The electronic apparatus according to claim 8, wherein a porosity of the heat sink is greater than or equal to 5% and is smaller than or equal to 95%.

10. The electronic apparatus according to claim 1, further comprising at least one insulation layer, wherein the at least one insulation layer wraps the at least one electronic module for insulating the at least one electronic module from the first coolant.

11. The electronic apparatus according to claim 1, wherein the first coolant is a nature water.
